(19) United States
(12) Patent Application Publication
(10) Pub. No.: US 2025/0210582 A1
(43) Pub. Date: Jun. 26, 2025

(54) DIE ATTACHING APPARATUS AND METHOD OF MANUFACTURING SEMICONDUCTOR PACKAGE USING THE SAME

(71) Applicant: SAMSUNG ELECTRONICS CO., LTD., Suwon-si (KR)

(72) Inventor: Jaewoo JEONG, Suwon-si (KR)

(21) Appl. No.: 18/960,277

(22) Filed: Nov. 26, 2024

(30) Foreign Application Priority Data
Dec. 20, 2023 (KR) 10-2023-0186954
Mar. 11, 2024 (KR) 10-2024-0033677

(51) Int. Cl. H01L 23/00

(52) U.S. Cl. CPC H01L 24/75; H01L 2224/75314; H01L 2224/75745; H01L 2224/75824

(57) ABSTRACT

A die attaching apparatus includes a collet body with a first vacuum passageway formed therein, and an adsorption member coupled with a bottom surface of the collet body. The adsorption member includes a first adsorption portion in the first region and having a first adsorption surface with a convex dome shape, and a second adsorption portion in a second region that extends peripherally around the first region and having a second adsorption surface. The second adsorption portion includes a plurality of second vacuum passageways formed therein that are in fluid communication with the first vacuum passageway.

### PRIORITY STATEMENT

This application claims priority under 35 U.S.C. § 119 to Korean Patent Application Nos. 10-2023-0186954, filed on Dec. 20, 2023 and 10-2024-0033677, filed on Mar. 11, 2024 in the Korean Intellectual Property Office (KIPO), the contents of which are herein incorporated by reference in their entireties.

### BACKGROUND

### 1. Field

Example embodiments relate to a die attaching apparatus and a method of manufacturing a semiconductor package using the same. More particularly, example embodiments relate to a die attaching apparatus having a chip transfer collet configured to pick up and transfer an individual die and a method of manufacturing a semiconductor package using the same.

### 2. Description of the Related Art

In manufacturing a multi-chip package (MCP), in order to stack memory chips on a controller chip having a relatively smaller size, a spacer chip with a dolmen structure may be placed around the controller chip to support the stacked memory chips. A die attaching apparatus having a chip transfer collet may be used to attach the memory chip on the controller and the spacer chip. In case that the memory chip is attached using an adhesive film such as DAF or FOW, there is a problem that the adhesive film may shrink during a curing process and may peel off at an interface of the adhesive film due to a height difference between the controller and the spacer chip. If a pressure for pressing the memory chip is increased in order to prevent such peeling, the adhesive film may bleed, causing a problem in that a molding material is not filled sufficiently under the memory chip during a subsequent molding process.

### SUMMARY

Example embodiments provide a die attaching apparatus that is able to improve a bonding quality of an adhesive film when attaching a die using the adhesive film.

Example embodiments provide a method of manufacturing the semiconductor package.

According to example embodiments, a die attaching apparatus includes a collet body having a first vacuum passageway, and an adsorption member coupled with a bottom surface of the collet body. The adsorption member includes a first adsorption portion in a first region of the adsorption member and that has a first adsorption surface with a convex dome shape, and a second adsorption portion in a second region that extends peripherally around the first region and that has a second adsorption surface. A plurality of second vacuum passageways extend through the second adsorption portion to the second adsorption surface and are in fluid communication with the first vacuum passageway.

According to example embodiments, a die attaching apparatus includes a collet body, and an adsorption member mounted in a bottom surface of the collet body. The adsorption member includes a first adsorption portion in a first region of the adsorption member and that has a first adsorption surface with a convex dome shape, and a second adsorption portion in a second region of the adsorption member that extends peripherally around the first region of the adsorption member and that has a second adsorption surface. A maximum distance that the first adsorption surface extends beyond the second adsorption surface is within a range of 10 μm to 20 μm.

According to example embodiments, a die attaching apparatus includes a collet body having a first vacuum passageway therein, and an adsorption member secured within a recessed portion in a bottom surface of the collet body. The adsorption member includes a plurality of second vacuum passageways that are in fluid communication with the first vacuum passageway. The adsorption member includes a first adsorption portion in a first region of the adsorption member and that has a first adsorption surface with a convex dome shape, and a second adsorption portion in a second region of the adsorption member that extends peripherally around the first region of the adsorption member and that has a second adsorption surface. The plurality of second vacuum passageways extend through the second adsorption portion to the second adsorption surface.

According to example embodiments, a die attaching apparatus may be used to attach a semiconductor chip such as a memory chip to a controller chip on a package substrate and spacer chips with a dolmen structure around the controller chip. One surface of the semiconductor chip may be adsorbed and supported on an adsorption surface of an adsorption member of the die attaching apparatus. The adsorption member may include a first adsorption portion having a first adsorption surface with a convex dome shape in a first region. A maximum height of the first adsorption surface may be equal to a height difference between the controller chip and the spacer chips. A radius of curvature of the first adsorption surface may correspond to the height difference between upper surfaces of the spacer chips and an upper surface of the controller chip.

Accordingly, when attaching the semiconductor chip to the upper surfaces of the controller chip and the spacer chips by the die attaching apparatus, the convex dome shaped first adsorption surface may generate pressure for good bonding between an adhesive film and the controller chip and may reduce pressure applied to the semiconductor chip and stress applied to the adsorption member.

### BRIEF DESCRIPTION OF THE DRAWINGS

Example embodiments will be more clearly understood from the following detailed description taken in conjunction with the accompanying drawings. FIGS. 1 to 16 represent non-limiting, example embodiments as described herein.

FIG. 1 is a cross-sectional view illustrating a die attaching apparatus in accordance with example embodiments.

FIG. 2 is a side view illustrating the die attaching apparatus in FIG. 1.

FIG. 3 is a bottom view illustrating an adsorption rubber of the die attaching apparatus in FIG. 1.

FIG. 4 is an exploded perspective view illustrating the die attaching apparatus in FIG. 1.

FIGS. 5 to 14 are views illustrating a method of manufacturing a semiconductor package in accordance with example embodiments.

FIG. 15 is a cross-sectional view illustrating a die attaching apparatus in accordance with example embodiments.

FIG. 16 is a side view illustrating the die attaching apparatus in FIG. 15.

### DETAILED DESCRIPTION OF EXAMPLE EMBODIMENTS

Hereinafter, example embodiments will be explained in detail with reference to the accompanying drawings.

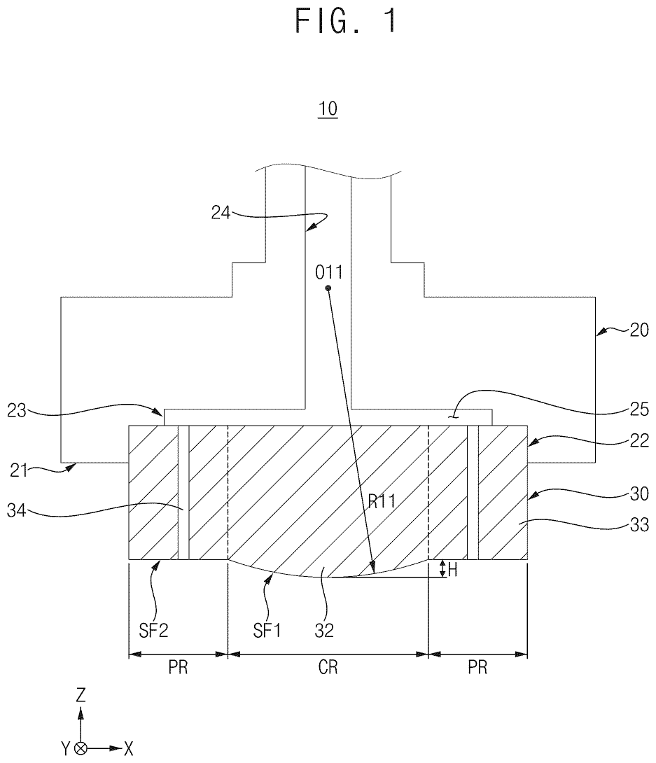

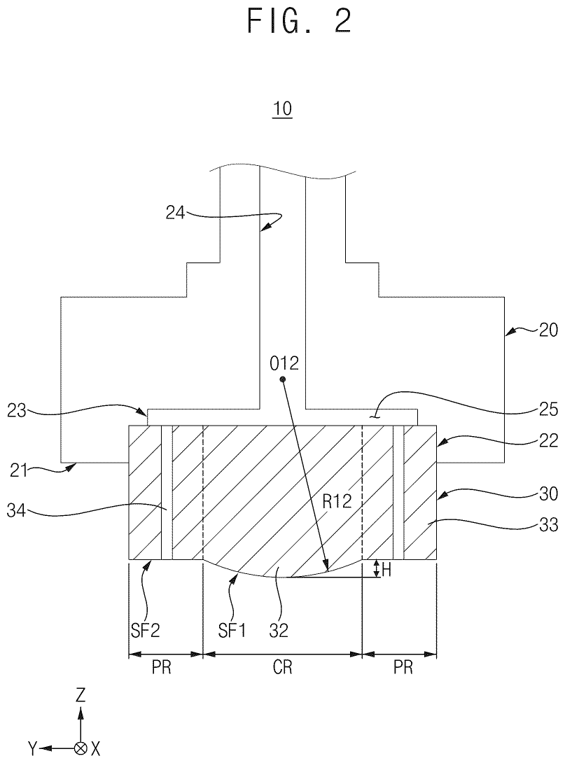

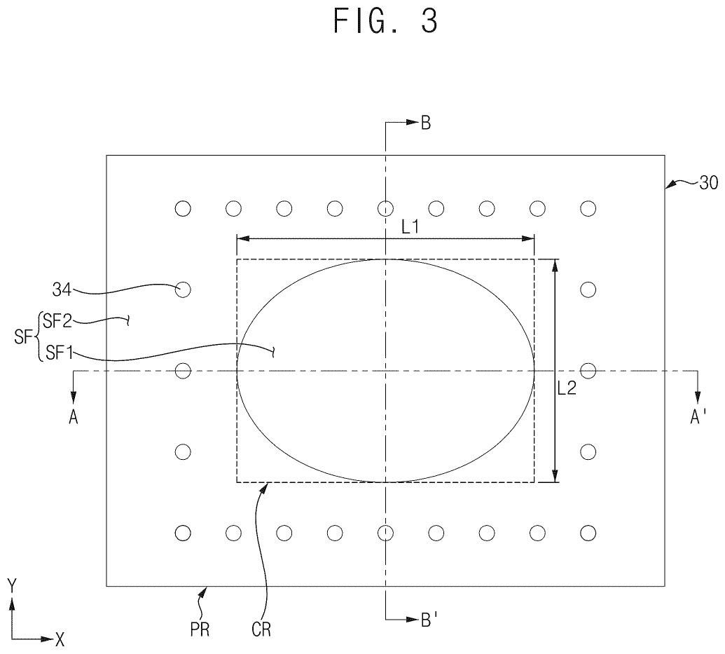

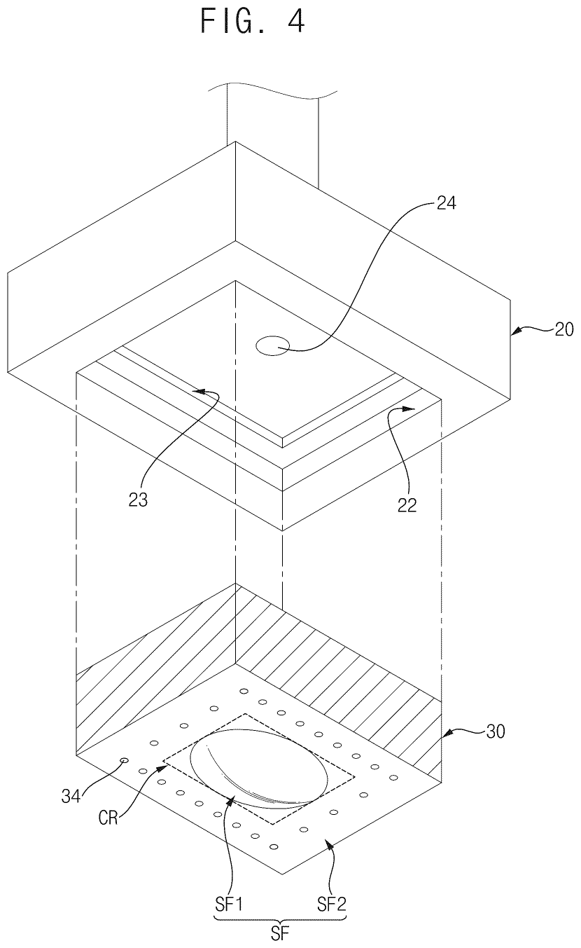

FIG. 1 is a cross-sectional view illustrating a die attaching apparatus in accordance with example embodiments. FIG. 2 is a side view illustrating the die attaching apparatus in FIG. 1. FIG. 3 is a bottom view illustrating an adsorption member of the die attaching apparatus in FIG. 1. The adsorption member may be formed from rubber or other elastomeric materials. FIG. 4 is an exploded perspective view illustrating the die attaching apparatus in FIG. 1. FIG. 1 includes a cross section cut along the line A-A′ in FIG. 3, and FIG. 2 includes a cross section cut along line B-B′ in FIG. 3.

Referring to FIGS. 1 to 4, a die attaching apparatus 10 may include a chip transfer collet and a driver in which the chip transfer collet is mounted. The chip transfer collet may include a collet body 20 and an adsorption member 30 that is mounted in a bottom surface 21 of the collet body 20 and has an adsorption surface SF for adsorbing a die. Additionally, the die attaching apparatus 10 may further include a vacuum generator that is connected to the collet body 20 to provide a vacuum pressure for adsorbing the die.

In example embodiments, the die attaching apparatus 10 may pick up a semiconductor chip individualized through a sawing process (or stacked chips) and attach it to a substrate such as a printed circuit board or another semiconductor chip. The driver may move the chip transfer collet that adsorbs the semiconductor chip coated with an adhesive film and to attach the adsorbed semiconductor chip to the substrate (or another chip). For example, the driver may move the collet body 20 in X, Y, and Z directions.

The collet body 20 may include an overall rectangular parallelepiped-shaped support block. At least one vacuum passage 24 (also referred to herein as a first vacuum passageway) may be formed in the collet body 20. The vacuum generator may include a vacuum pump, valve, etc., and may be in communication with the vacuum passage 24. The adsorption member 30 may include an overall rectangular parallelepiped-shaped rubber (or other elastomeric material) block. The adsorption member 30 may be coupled with the bottom surface 21 of the collet body 20. The bottom of the adsorption member 30 may be provided as the adsorption surface SF. The adsorption surface SF of the adsorption member 30 may have an area corresponding to an area of the die. For example, the adsorption surface SF of the adsorption member 30 may be equal to or smaller than the area of one surface of the die. A plurality of suction holes or vacuum passageways 34 (also referred to herein as second vacuum passageways) may be formed in the adsorption member 30 to be in communication with the vacuum passage 24 (also referred to herein as a first vacuum passageway) of the collet body 20 to vacuum suction the die (i.e., to temporarily secure the die to the adsorption surface SF when vacuum is created in the vacuum passageways 34). Lower end portions of the vacuum passageways 34 may be exposed from the adsorption surface SF of the adsorption member 30. As illustrated in FIG. 4, a coupling groove 22 may be formed in the bottom surface 21

of the collet body 20, and an upper portion of the adsorption member 30 may be fitted into the coupling groove 22. A groove 23 may be formed in the coupling groove 22 of the collet body 20 to form a space in fluid communication with the vacuum passage 24, and the adsorption member 30 may be coupled with the bottom of the collet body 20 to form a vacuum forming space 25. As the plurality of vacuum passageways 34 communicate with the vacuum forming space 25, the vacuum generator may communicate with the plurality of vacuum passageways 34. Accordingly, the adsorption member 30 may adsorb and support one surface of the die using vacuum.

Although not illustrated in the figures, the die attaching apparatus 10 may further include a heater that is provided in the collet body 20. The heater may include an electric resistance heating wire provided in the collet body 20. The heater may increase a temperature of the die that is adsorbed and supported on the adsorption surface SF of the adsorption member 30.

In example embodiments, the adsorption member 30 may include a first adsorption portion 32 provided in a first region CR and a second adsorption portion 33 provided in a second region PR surrounding (i.e., extending peripherally around) the first region CR. The first adsorption portion 32 may have a first adsorption surface SF1 with a convex dome shape, as illustrated. The second adsorption portion 33 may have a second adsorption surface SF2 of a flat planar shape, as illustrated. The first adsorption surface SF1 may have a radius of curvature of 25 mm to 625 mm. A maximum height H of the first adsorption surface SF1 relative to the second adsorption surface SF2 may be within a range of 10 μm to 20 μm (i.e., the height H is the distance the first adsorption surface SF1 extends beyond or outward from the second adsorption surface SF2). The plurality of vacuum passageways 34 may be formed in the second adsorption portion 33. The plurality of vacuum passageways 34 may be spaced apart from each other along a peripheral region of the adsorption member 30 within the second region PR.

As illustrated in FIG. 3, when viewed in plan view, the first region CR may correspond to a central region of the surface of the die to be adsorbed, and the second region PR may correspond to a peripheral region of the surface of the die. As described later, the first region CR may correspond to a tunnel region (internal region surrounded by spacer chips) that has a rectangular shape, and a length of one side of the first region CR may be within a range of 2 mm to 8 mm.

The first adsorption portion 32 may have an oval shape when viewed in plan view. A length L1 in a first direction (X direction) of the first region CR may be within a range of 4 mm to 8 mm. A length L2 in a second direction (Y direction) of the first region CR may be within a range of 2 mm to 6 mm. A cross section of the first adsorption portion 32 along a major axis direction of the oval shape may have a first radius of curvature R11, and a cross section of the first adsorption portion 32 along a minor axis direction may have a second radius of curvature R12. The second radius of curvature R12 may be greater than the first radius of curvature R11.

In example embodiments, the die attaching apparatus 10 may be used to attach a memory chip to a controller chip on a package substrate and spacer chips in a dolmen structure around the controller chip. A wafer to which an adhesive film such as DAF (direct adhesive film) or FOW (film over wire) is adhered may be diced into individual semiconductor chips, and the die attaching apparatus 10 may adsorb one surface of the semiconductor chip and may attach the semiconductor chip to the controller chip and the spacer chips using the adhesive film.

In this case, the controller chip may be disposed within an internal region surrounded by the spacer chips, that is, a tunnel region. When attaching the controller chip and the spacer chips to the package substrate, the height of the controller chip from the package substrate may be less than the height of the spacer chip due to process tolerances, etc. Due to the height difference between the controller and the spacer chip, the adhesive film such as DAF or FOW may not be well attached to the upper surfaces of the controller chip and the spacer chips. The height difference between the controller chip and the spacer chips may be within a range of 10 μm to 20 μm.

As mentioned above, one surface of the semiconductor chip may be adsorbed and supported on the adsorption surface SF of the adsorption member 30 of the die attaching apparatus 10. The adsorption member 30 may include the first adsorption portion 32 having the convex dome shaped first adsorption surface SF1 in the first region CR corresponding to the tunnel region. The maximum height of the first adsorption surface SF1 may be equal to the height difference between the controller chip and the spacer chips. The radius of curvature of the first adsorption surface SF1 may correspond to the difference between the upper surfaces of the spacer chips and the upper surface of the controller chip. Accordingly, when attaching the semiconductor chip to the upper surfaces of the controller chip and the spacer chips by the die attaching apparatus 10, the convex dome shaped first adsorption surface SF1 may generate pressure for good bonding between the adhesive film and the controller ship and may reduce pressure applied to the semiconductor chip and stress applied to the adsorption member 30.

Hereinafter, a method of manufacturing a semiconductor package using the die attaching apparatus will be described.

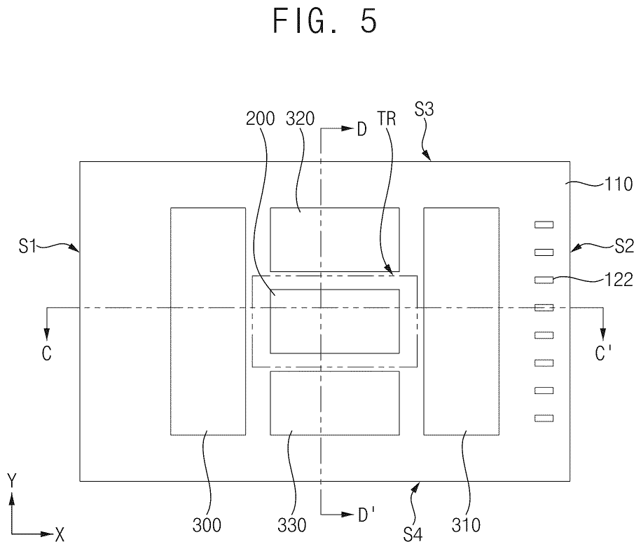

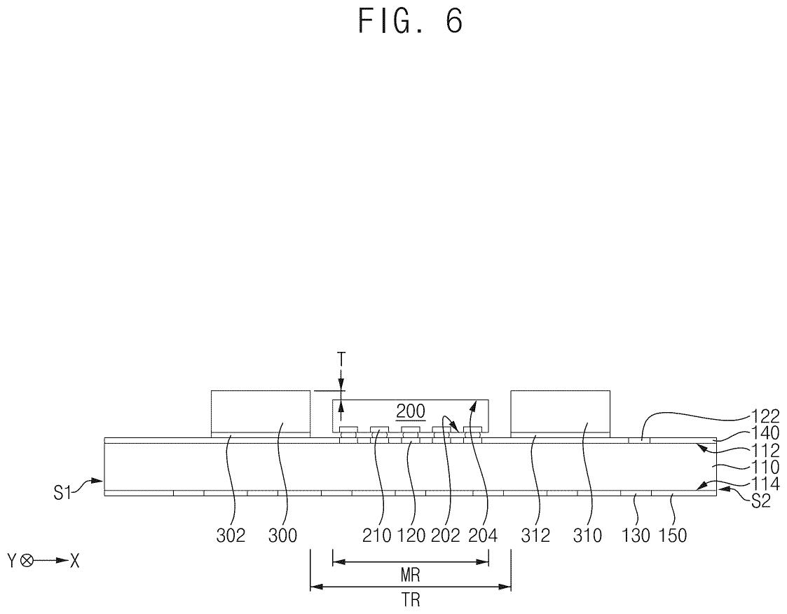

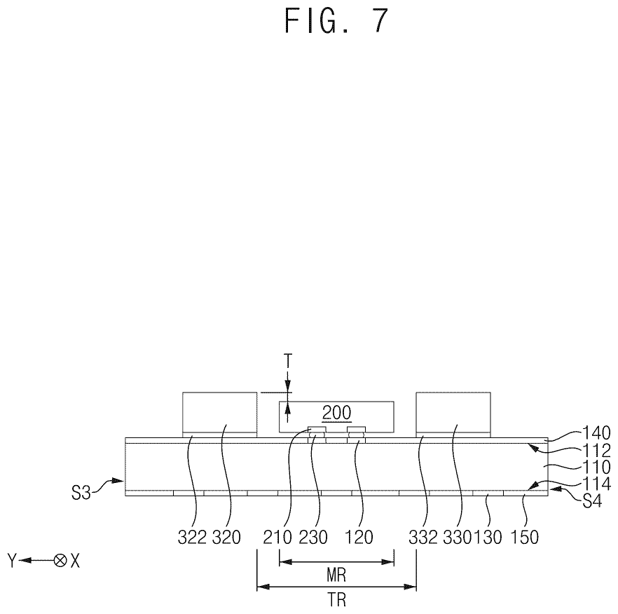

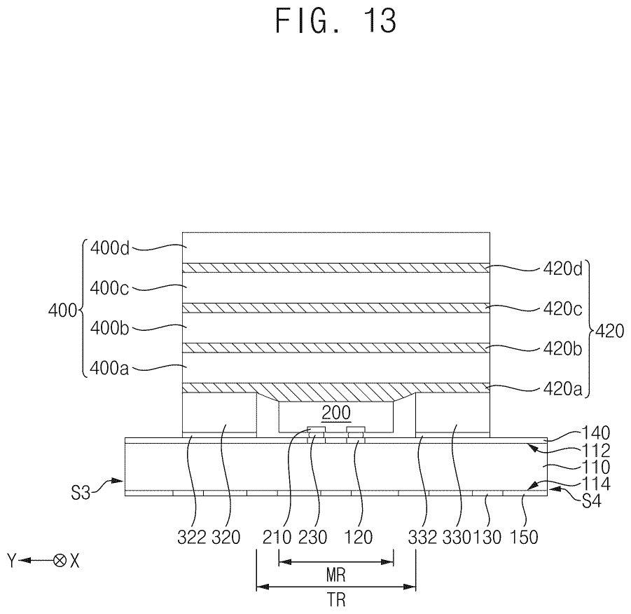

FIGS. 5 to 14 are views illustrating a method of manufacturing a semiconductor package in accordance with example embodiments. FIG. 5 is a plan view illustrating a package substrate on which a controller chip and spacer chips are arranged. FIGS. 6, 8, 10, 12 and 14 are cross-sectional views taken along the line C-C′ in FIG. 5. FIGS. 7, 9, 11 and 13 are cross-sectional views taken along the line D-D′ in FIG. 5.

Referring to FIGS. 5 to 7, a first semiconductor chip 200 and a plurality of spacer chips 300, 310, 320, and 330 may be disposed on a package substrate 110.

In example embodiments, the package substrate 110 may be a substrate having an upper surface 112 and a lower surface 114 opposite to the upper surface 112. For example, the package substrate 110 may be a printed circuit board (PCB). The printed circuit board may be a multilayer circuit board having vias and various circuits therein. The package substrate 110 may include internal wirings that serve as channels for electrical connection with first and second semiconductor chips, which will be described later.

The package substrate 110 may include a first side portion S1 and a second side portion S2 extending in a direction parallel to the second direction (Y direction) and facing away from each other (i.e., the first side portion S1 and the second side portion S2 are opposing side portions), and a third side portion S3 and a fourth side portion S4 that extend in a direction parallel to the first direction (X direction) perpendicular to the direction and that face away from each other (i.e., the third side portion S3 and the fourth side portion S4 are opposing side portions).

The package substrate 110 may have a chip mounting region MR in a central region thereof. As will be described later, the chip mounting area MR may be an area where a first semiconductor chip as a controller chip is mounted. The chip mounting area MR may have a rectangular shape.

For example, a width of the package substrate 110 in the first direction (X direction) may be within a range of 10 mm to 15 mm, and a width of the package substrate 110 in the second direction (Y direction) may be within a range of 4 mm to 7 mm. One side of the chip mounting region MR may have a length within a range of 2 mm to 4 mm.

The package substrate 110 may include first substrate pads 120 arranged in the chip mounting region MR and second substrate pads 122 arranged along the second side portion S2 of the package substrate 110. The first and second substrate pads 120 and 122 may be respectively connected to the wirings. The wirings may extend on the upper surface 112 of the package substrate 110 or within the package substrate 110. For example, at least a portion of the wiring may be used as a substrate pad, that is, a landing pad.

Although only a few substrate pads are illustrated in the figures, it will be understood that the number, shape, and arrangement of the substrate pads are provided as examples, and the present inventive concept is not limited thereto.

A first insulating layer 140 may be formed on the upper surface 112 of the package substrate 110 to expose the first and second substrate pads 120 and 122 (i.e., the first and second substrate pads 120, 122 are exposed at the first insulating layer 140, as illustrated). The first insulating layer 140 may cover the entire upper surface 112 of the package substrate 110 excluding the first and second substrate pads 120 and 122. For example, the first insulating layer may include a solder resist.

In example embodiments, the first semiconductor chip 200 may be mounted on the package substrate 110 via conductive bumps 230. The first semiconductor chip 200 may be disposed such that a front surface 202 on which first chip pads 210 are formed, that is, an active surface, faces the package substrate 110. The first semiconductor chip 200 may have a rectangular shape with four sides when viewed in plan view. The first chip pads 210 may be arranged in an array form over the entire front surface 202 of the first semiconductor chip 200. The first semiconductor chip 200 may be a logic chip including a logic circuit. The logic chip may be a controller that controls memory chips. The first semiconductor chip may be a processor chip or an application processor AP such as an ASIC as a host such as CPU, GPU, or SOC.

The first semiconductor chip 200 may be mounted on the package substrate 110 using a flip chip bonding method. The first chip pads 210 of the first semiconductor chip 200 may be electrically connected to the first substrate pads 120 of the package substrate 110 by the conductive bumps 230, for example, solder bumps.

For example, a thickness of the first semiconductor chip 200 may be within a range of 90 μm to 110 μm. A height of the first semiconductor chip 200 from the upper surface 112 of the package substrate 110 may be within a range of 125 μm to 160 μm.

Alternatively, after attaching the first semiconductor chip to the upper surface 112 of the package substrate 110 using an adhesive film, a wire bonding process may be performed to connect the first chip pads of the first semiconductor chip to the substrate pads on the upper surface 112 of the substrate 110. The first chip pads of the first semiconductor chip may be connected to the substrate pads by conductive connection members. The conductive connection members may include bonding wires.

In example embodiments, first, second, third and fourth spacer chips 300, 310, 320, and 340 may be arranged on the package substrate 110 to surround the first semiconductor chip 200. The first to fourth spacer chips 300, 310, 320, and 330 may be attached to the upper surface 112 of the package substrate 110 using adhesive films 302, 312, 322, and 332 to be spaced apart from each other.

The first and second spacer chips 300 and 310 may be arranged to be spaced apart from each other in the first direction (X direction) with the chip mounting region MR interposed therebetween. The third and fourth spacer chips 320 and 330 may be spaced apart from each other in the second direction (Y direction) with the chip mounting region MR interposed therebetween. The first, second, third and fourth spacer chips 300, 310, 320, and 330 may be formed by cutting a silicon wafer W through a sawing process, and then, may be attached to the upper surface 112 of the package substrate 110 using the adhesive films 302, 312, 322, and 332 through a die attach process.

In example embodiments, the internal region surrounded by the first, second, third and fourth spacer chips 300, 310, 320, and 330 may be referred to as the tunnel region TR. The first semiconductor chip 200 may be disposed within the tunnel region TR. The tunnel region TR may have a rectangular shape. A length of one side of the tunnel region TR may be within a range of 2 mm to 8 mm. A length of the tunnel region TR in the first direction (X direction) may be within a range of 4 mm to 8 mm. A length of the tunnel region TR in the second direction (Y direction) may be within a range of 2 mm to 6 mm.

A height of the first semiconductor chip 200 may be less than the respective heights of the first to fourth spacer chips 300, 310, 320, and 330. When attaching the first semiconductor chip 200 and the spacer chips 300, 310, 320, and 330 on the package substrate 110, the height of the first semiconductor chip 200 from the package substrate 110 may be less than the respective heights of the spacer chips 300, 310, 320, and 330 from the package substrate 110 due to process tolerances, etc. A height difference T between the first semiconductor chip 200 and the spacer chips 300, 310, 320, and 330 may be within a range of 10 μm to 20 μm.

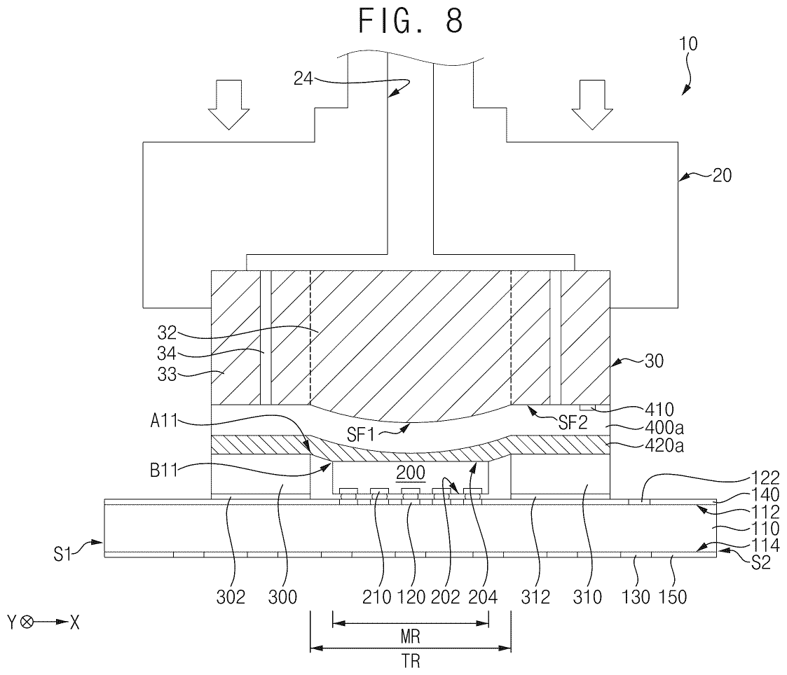

Referring to FIGS. 8 to 13, a plurality of second semiconductor chips 400 may be attached to the first to fourth spacer chips 300, 310, 320, and 330 using an adhesive film 420.

As illustrated in FIGS. 8 to 11, a lowermost second semiconductor chip 400a may be attached on the first semiconductor chip 200 and the first to fourth spacer chips 300, 310, 320, 330 using a first adhesive film 420a. The second semiconductor chip 400a may be attached to the first semiconductor chip 200 and the first to fourth spacer chips 300, 310, 320, 330 using the first adhesive film 320a such as DAF or FOW by a die attaching apparatus 10 of FIG. 1.

The second semiconductor chip 400a may be disposed such that a backside surface, that is, an inactive surface opposite to a front surface on which second chip pads 310 are formed, faces the package substrate 110. The second semiconductor chip 400a may have a rectangular shape with four sides when viewed in plan view.

The second semiconductor chip may include a memory chip including a memory circuit. For example, the second semiconductor chip may include volatile memory devices such as SRAM devices, DRAM devices, and non-volatile memory devices such as flash memory devices, PRAM devices, MRAM devices, RRAM devices, etc.

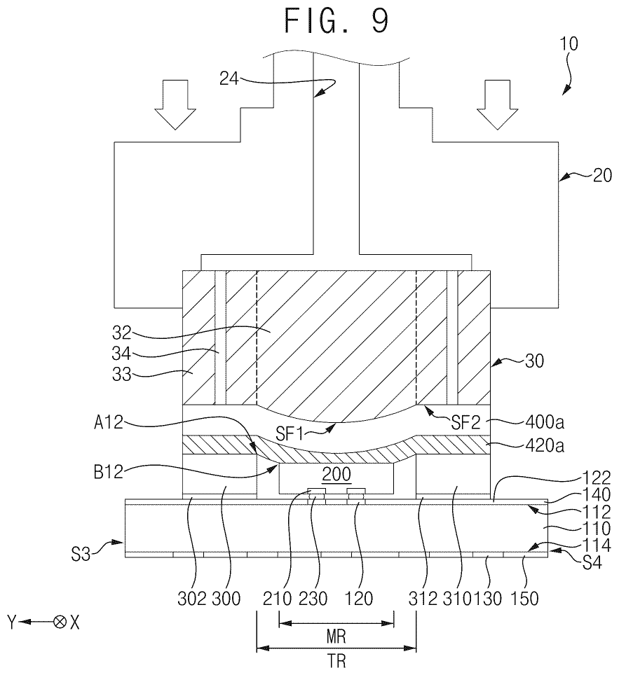

As illustrated in FIGS. 8 and 9, in example embodiments, the first adhesive film 420a may be attached to the backside surface of the second semiconductor chip 400a, and one surface of the second semiconductor chip 400a having the first adhesive film 420a attached thereon may be adsorbed and supported on adsorption surfaces SF1 and SF2 of an adsorption member 30 of the die attaching apparatus 10. The second semiconductor chip 400a may be pressed onto the first to fourth spacer chips 300, 310, 320, and 330 by the die attaching apparatus 10, and may be heated to high temperatures by a heater block in a support system supporting the package substrate 110. For example, the second semiconductor chip 400a may be pressurized to a pressure of 0.6 MPa at a temperature of 140° C. A thickness of the first adhesive film 420a may be within a range of 60 μm to 120 μm.

The adsorption member 30 may include a first adsorption portion 32 that has a first adsorption surface SF1 with a convex shape in a first region CR corresponding to the tunnel region TR. A maximum height of the first adsorption surface SF1 may be equal to or similar to the height difference T between the first semiconductor chip 200 and the spacer chips 300, 310, 320, and 330. A radius of curvature of the first adsorption surface SF1 may correspond to the difference between upper surfaces of the spacer chips 300, 310, 320, and 330 and an upper surface of the first semiconductor chip 200.

When pressing the collet adsorption member 30, which has a rounded shape corresponding to a step shape between the first semiconductor chip 200 and the spacer chips 300, 310, 320, and 330, on the second semiconductor chip 400a, even with a small pressing force (stress) applied to the collet adsorption member 30, the second semiconductor chip 400a may be rapidly deformed along the step shape to improve bonding strength. Accordingly, the pressing force on the adhesive film 420a between the first semiconductor chip 200 and the second semiconductor chip 400a may be increased to thereby increase the adhesive force at edge portions B11 and B12 of the first semiconductor chip 200. Additionally, the pressing force on the adhesive film 420a between the spacer chips 300, 310, 320, 330 and the second semiconductor chip 400a may be reduced to thereby prevent the adhesive film 420 from bleeding at edge portions All and A2 of the spacer chips 300, 310, 320, 330.

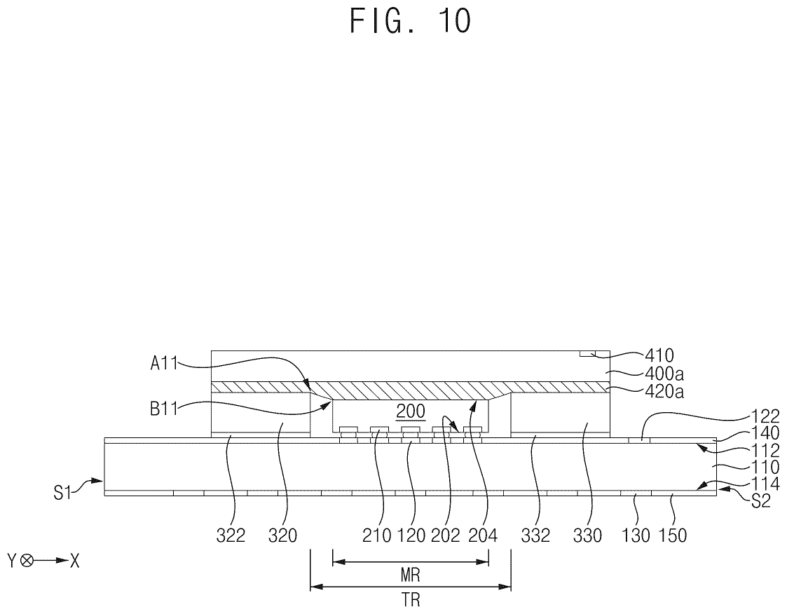

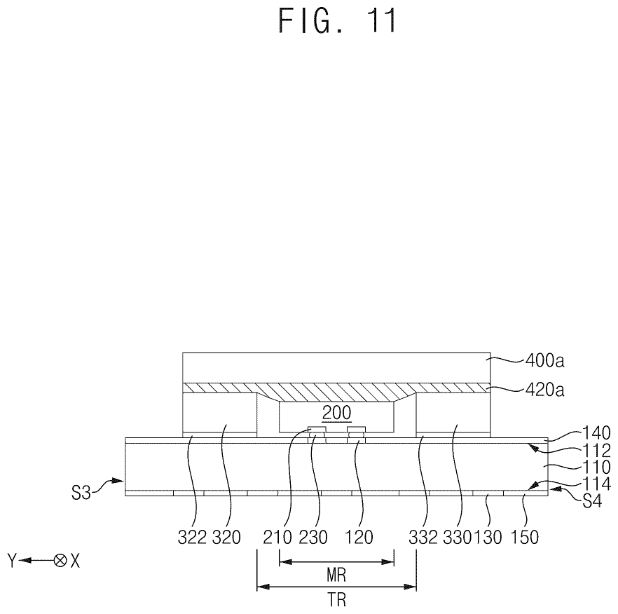

As illustrated in FIGS. 10 and 11, the pressing force applied to the second semiconductor chip 400a may be removed, the adhesive film 420a may be cured, and even though the second semiconductor chip 400a is released from the die attaching apparatus 10, an adhesive force between the adhesive film 420a and the second semiconductor chip 400a may be maintained.

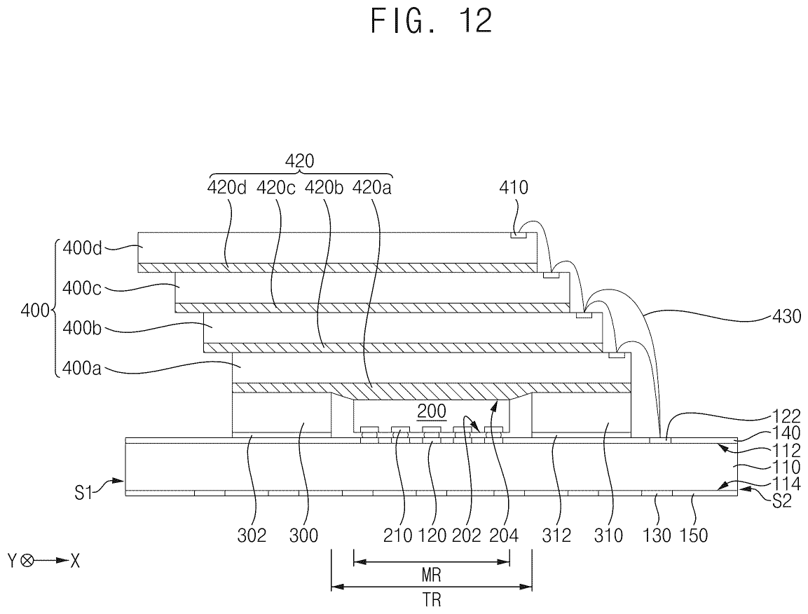

Then, as illustrated in FIG. 12, the remaining chips 400b, 400c, 400d among the plurality of second semiconductor chips 400 may be sequentially attached on the lowermost second semiconductor chip 400a. The second semiconductor chips 400b, 400c, and 400d may be sequentially attached on the lowermost second semiconductor chip 400a using second adhesive films 420b, 420c, and 420d such as a die attach film (DAF) through a die attach process. Thicknesses of the second adhesive films 420b, 420c, and 420d may be within a range of 10 μm to 20 μm.

A planar area of the second semiconductor chip may be greater than a planar area of the first semiconductor chip or the space chip. Accordingly, the second semiconductor chips 400a, 400b, 400c, and 400d may be supported and mounted on the package substrate 110 by the first to fourth spacer chips 300, 310, 320, and 330.

The plurality of second semiconductor chips 400a, 400b, 400c, and 400d may be sequentially offset aligned, as illustrated in FIG. 12. For example, the second semiconductor chips 400a, 400b, 400c, and 400d may be stacked in a cascade or staircase structure. The second semiconductor chips 400a, 400b, 400c, and 400d may be sequentially offset aligned in a first lateral direction (−X direction) of the package substrate 110.

The number, sizes, arrangements, etc. of the second semiconductor chips are provided as examples, and it will be understood that the present inventive concept is not limited thereto. Additionally, although only a few second chip pads are illustrated in the figures, the structures, shapes, and arrangements of the second chip pads are provided as examples, and it will be understood that the present inventive concept is not limited thereto.

Then, the second semiconductor chips 400 may be electrically connected to the package substrate 110 through conductive connection members 430.

In example embodiments, a wire bonding process may be performed to connect the second chip pads 410 of the second semiconductor chips 400 to the second substrate pads 122 on the upper surface 112 of the package substrate 110 using bonding wires 430.

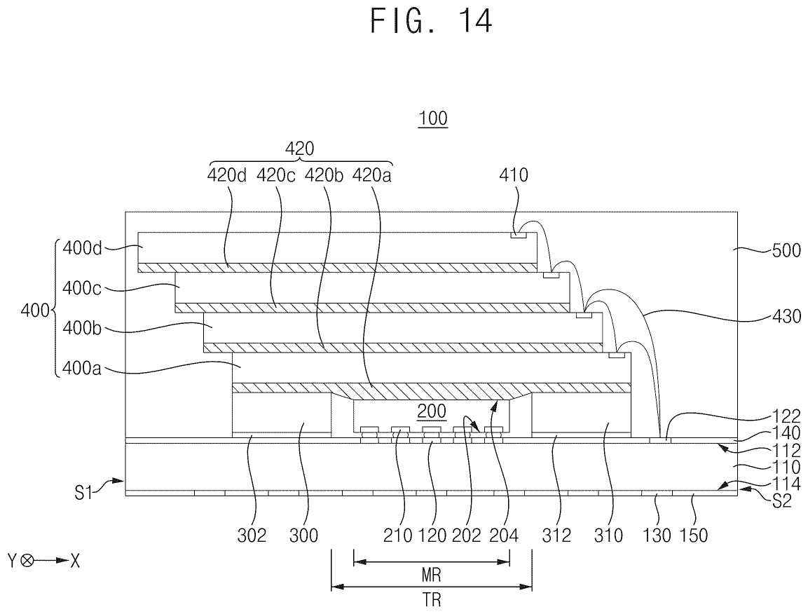

Referring to FIG. 14, a molding member 500 may be formed on the upper surface 112 of the package substrate 110 to cover the first semiconductor chip 200, the first to fourth spacer chips 300, 310, 320, and 330, the second semiconductor chips 400, and the bonding wires 430. The sealing member may include a thermosetting resin, for example, epoxy mold compound (EMC).

Then, external connection members may be formed on external connection pads 130 on the lower surface 114 of the package substrate 110 to complete the semiconductor package 100 of FIG. 1.

For example, the external connection members may include solder balls. The external connection members may be respectively formed on the external connection pads 130 on the lower surface 114 of the package substrate 110 through a solder ball attach process.

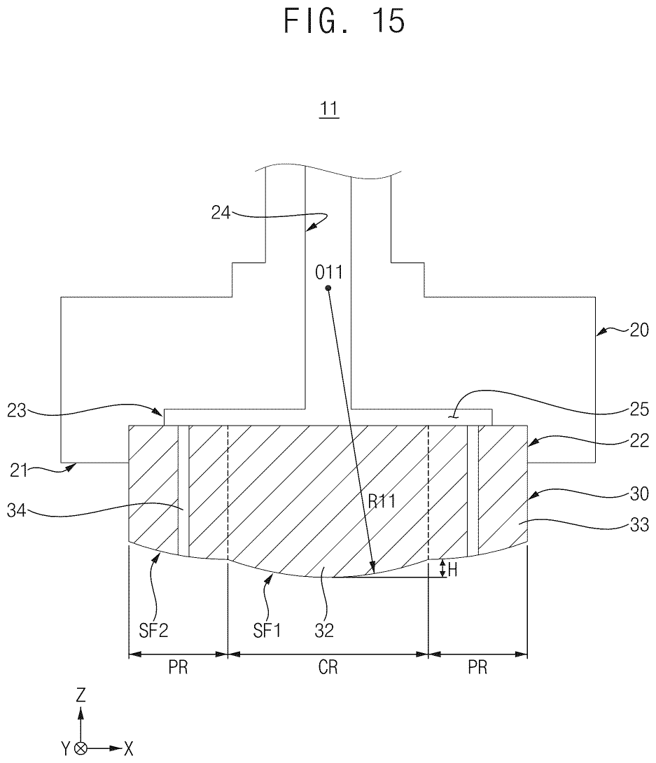

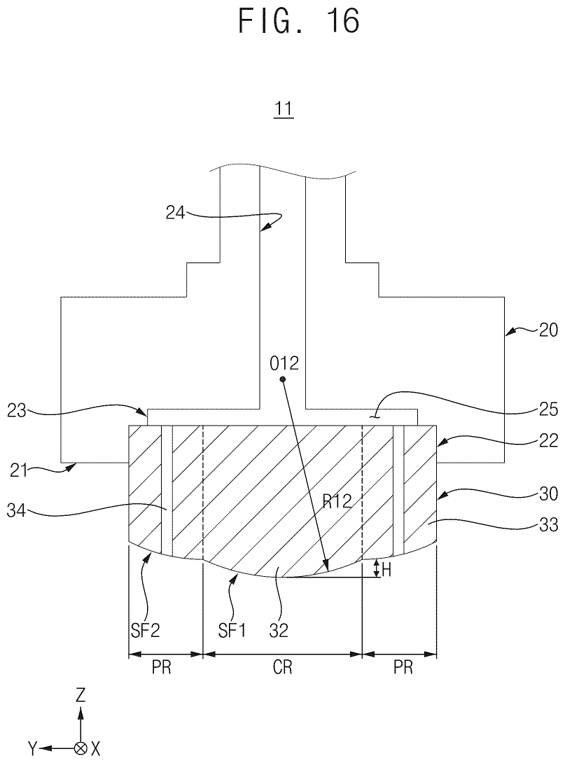

FIG. 15 is a cross-sectional view illustrating a die attaching apparatus in accordance with example embodiments. FIG. 16 is a side view illustrating the die attaching apparatus in FIG. 15. The die attaching apparatus is substantially the same as or similar to the die attaching apparatus described with reference to FIGS. 1 to 4 except for a configuration of a second adsorption portion of an adsorption member. Thus, same reference numerals will be used to refer to the same or like elements and any further repetitive explanation concerning the above elements will be omitted.

Referring to FIGS. 15 and 16, a die attaching apparatus 11 may include a collet body 20 and an adsorption member 30 that is mounted in a bottom surface 21 of the collet body 20 and has an adsorption surface SF for adsorbing a die.

In example embodiments, the adsorption member 30 may include a first adsorption portion 32 provided in a first region CR and a second adsorption portion 33 provided in a second region PR surrounding the first region CR. The first adsorption portion 32 may have a first adsorption surface SF1 of a convex dome shape. The second adsorption portion 33 may have a second adsorption surface SF2 of a convex shape. The second adsorption surface SF2 having the convex shape may have a radius of curvature greater than that of the first adsorption surface SF1.

A plurality of vacuum passageways 34 may be formed in the second adsorption portion 33. The plurality of vacuum passageways 34 may be spaced apart from each other along a peripheral region of the adsorption member 30 within the second region PR.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A die attaching apparatus, comprising:
a collet body comprising a first vacuum passageway therein; and
an adsorption member coupled with a bottom surface of the collet body,
wherein the adsorption member comprises:
a first adsorption portion in a first region of the adsorption member, wherein the first adsorption portion comprises a first adsorption surface having a convex dome shape; and
a second adsorption portion in a second region of the adsorption member that extends peripherally around the first region of the adsorption member, wherein the second adsorption portion comprises a second adsorption surface, and wherein a plurality of second vacuum passageways extend through the second adsorption portion to the second adsorption surface and are in fluid communication with the first vacuum passageway.

2. The die attaching apparatus of claim 1, wherein the first adsorption surface has a radius of curvature of 25 mm to 625 mm.

3. The die attaching apparatus of claim 1, wherein a maximum distance that the first adsorption surface extends beyond the second adsorption surface is within a range of 10 μm to 20 μm.

4. The die attaching apparatus of claim 1, wherein the first region of the adsorption member corresponds to a tunnel region of a package substrate, wherein the tunnel region has a rectangular shape, and wherein a length of one side of the tunnel region is within a range of 2 mm to 8 mm.

5. The die attaching apparatus of claim 1, wherein the first adsorption portion has an oval shape when viewed in a bottom plan view, and
wherein a cross section of the first adsorption portion along a major axis direction of the oval shape has a first radius of curvature, and a cross section of the first adsorption portion along a minor axis direction of the oval shape has a second radius of curvature.

6. The die attaching apparatus of claim 1, wherein the second adsorption surface has a flat planar shape or a convex shape.

7. The die attaching apparatus of claim 1, wherein the second adsorption surface has a convex shape with a radius of curvature greater than a radius of curvature of the first adsorption surface.

8. The die attaching apparatus of claim 1, wherein a surface of a die is adsorbed on the first adsorption surface and the second adsorption surface of the adsorption member when vacuum is provided to the plurality of second vacuum passageways via the first vacuum passageway.

9. The die attaching apparatus of claim 1, wherein the adsorption member is secured within a recessed portion in the bottom surface of the collet body.

10. The die attaching apparatus of claim 9, wherein the recessed portion comprises a groove that is in fluid communication with the first vacuum passageway, and wherein the plurality of second vacuum passageways in the adsorption member are in fluid communication with the groove when the adsorption member is coupled with the bottom of the collet body.

11. A die attaching apparatus, comprising:
a collet body; and
an adsorption member mounted in a bottom surface of the collet body wherein the adsorption member comprises:
a first adsorption portion in a first region of the adsorption member, wherein the first adsorption portion comprises a first adsorption surface having a convex dome shape; and
a second adsorption portion in a second region of the adsorption member that extends peripherally around the first region of the adsorption member, wherein the second adsorption portion comprises a second adsorption surface,
wherein a maximum distance that the first adsorption surface extends beyond the second adsorption surface is within a range of 10 μm to 20 μm.

12. The die attaching apparatus of claim 11, wherein the first adsorption surface has a radius of curvature of 25 mm to 625 mm.

13. The die attaching apparatus according to claim 11, wherein the first region of the adsorption member corresponds to a tunnel region of a package substrate, wherein the tunnel region has a rectangular shape, and a length of one side of the tunnel region is within a range of 2 mm to 8 mm.

14. The die attaching apparatus of claim 11, wherein the first adsorption portion has an oval shape when viewed in a bottom plan view, and
wherein a cross section of the first adsorption portion along a major axis direction of the oval shape has a first radius of curvature, and a cross section of the first adsorption portion along a minor axis direction of the oval shape has a second radius of curvature.

15. The die attaching apparatus according to claim 11, wherein the second adsorption surface has a flat planar shape or a convex shape.

16. The die attaching apparatus of claim 11, wherein the second adsorption surface has a convex shape with a second radius of curvature greater than a first radius of curvature of the first adsorption surface.

17. The die attaching apparatus of claim 11, wherein the collet body comprises a first vacuum passageway, and wherein the adsorption member comprises a plurality of second vacuum passageways that are in fluid communication with the first vacuum passageway.

18. The die attaching apparatus of claim 17, wherein the plurality of second vacuum passageways extend through the second adsorption portion of the adsorption member.

19. The die attaching apparatus of claim 17, wherein the adsorption member is secured within a recessed portion in the bottom surface of the collet body, wherein the recessed portion comprises a groove that is in fluid communication with the first vacuum passageway, and wherein the plurality of second vacuum passageways in the adsorption member are in fluid communication with the first vacuum passageway via the groove.

20. A die attaching apparatus, comprising:
a collet body comprising a first vacuum passageway therein; and
an adsorption member secured within a recessed portion in a bottom surface of the collet body, the adsorption member comprising a plurality of second vacuum passageways that are in fluid communication with the first vacuum passageway,
wherein the adsorption member comprises:
a first adsorption portion in a first region of the adsorption member, wherein the first adsorption portion comprises a first adsorption surface having a convex dome shape; and
a second adsorption portion in a second region of the adsorption member that extends peripherally around the first region of the adsorption member, wherein the second adsorption portion comprises a second adsorption surface, and wherein the plurality of second vacuum passageways extend through the second adsorption portion to the second adsorption surface.
